(19) United States
(12) Patent Application Publication
(10) Pub. No.: US 2018/0022079 A1
(43) Pub. Date: Jan. 25, 2018

(54) METHOD AND DEVICE FOR DETACHING A SUBSTRATE FROM A SUBSTRATE STACK

(71) Applicant: EV GROUP E. THALLNER GMBH, St. Florian am Inn (AT)

(72) Inventor: Jurgen BURGGRAF, Scharding (AT)

(73) Assignee: EV GROUP E. THALLNER GMBH, St. Florian am Inn (AT)

(21) Appl. No.: 15/540,282

(22) PCT Filed: Jan. 14, 2015
(86) PCT No.: PCT/EP2015/050607

§ 371 Date: Jun. 28, 2017

(51) Int. Cl. B32B 43/00; H01L 21/67; C09J 5/06; H01L 21/683

(52) U.S. Cl. CPC B32B 43/006; H01L 21/6836; H01L 21/67132; C09J 5/06; H01L 2221/68318; H01L 2221/68381; B32B 2310/0806; C09J 2483/00

(57) ABSTRACT

A method and device for detaching a carrier substrate from a substrate stack, which is formed by the carrier substrate and a product substrate, as well as a bonding layer bonding the carrier substrate and the product substrate. The bonding layer has an adhesive strength for bonding the carrier substrate and the product substrate, and the adhesive strength is at least partially reduced by a beam of electromagnetic radiation directed at least predominantly on the bonding layer.

### FIELD OF THE INVENTION

The invention relates to a method and a device for detaching a substrate from a substrate stack.

### BACKGROUND OF THE INVENTION

Industry uses so-called temporary bonding methods in order to temporarily bond two substrates with one another, in particular two wafers. In most cases, one of the two substrates is a carrier substrate. The second substrate is the product substrate. Functional units such as for example microchips, MEMs, LEDs etc. are produced on the product substrate. The product substrate very often has to be back-thinned in a further process step. A back-thinning process is understood to be a process in which the thickness of a substrate is markedly reduced, i.e. to approx. 50 μm, with the aid of various process technologies, in particular mechanical grinding. A stabilisation usually takes place by means of a carrier substrate.

There are various methods in industry for the temporary fixing of two substrates. One of the most important methods is the so-called ZoneBOND® method, which is described for example in publication WO2009094558A2. In the ZoneBOND® method, a carrier substrate is prepared with a special treatment, in such a way that only the outer edge of the carrier substrate is still capable of producing an adhesive strength with respect to an applied adhesive, whereas the adhesion between the centre of the carrier substrate and the adhesive is much less, in particular negligibly small. Thus, it is possible to apply a curable adhesive layer over the whole area on a carrier substrate, but to bond it solely along the periphery to the carrier substrate. The detachment of the product substrate is correspondingly easy. A ZoneBOND® carrier is characterised by a low-adhesion central zone and a highly adhesive edge zone. The low-adhesion central zone is usually achieved by a central coating of the carrier substrate. The adhesive is then applied over the entire area on the carrier and has at the periphery correspondingly greater adhesive properties than in the centre.

The most frequently used method for dissolving the periphery of a ZoneBOND® carrier is the use of chemicals. In order to be able to use such chemical baths for the detachment (debonding), one is limited to the use of adhesives which dissolve in the chemical and at least reduce their adhesive strength. Chemical dissolution processes are correspondingly slow, since the adhesive must first be detached and then carried away. Furthermore, an advancing detachment of the adhesive contaminates the solution bath, which contributes towards an albeit slow, but steady slowing-down of the dissolution process. This problem is solved for example by a continuous supply and discharge of the solvent, which however leads to an increased consumption of solvent.

The problem of the present invention is to develop the generic devices and methods for detaching first substrates, in such a way that a careful and rapid detachment is enabled. At the same time, the scope of use is to be extended to diverse types of adhesive and substrate materials.

This problem is solved with the features of the independent claim(s). Advantageous developments of the invention are given in the sub-claims. All combinations of at least two features given in the description, the claims and/or the figures also fall within the scope of the invention. In value ranges, values lying inside the stated limits are also deemed to be disclosed as limiting values and can be claimed in any combination.

### SUMMARY OF THE INVENTION

The basic idea of the present invention is that, by means of a beam of electromagnetic radiation directed at least predominantly onto the bonding layer, the adhesive strength of the bonding layer (referred to hereinafter in particular as adhesive) with respect to the product substrate and/or with respect to the carrier substrate is reduced at least in part or the adhesive is even removed completely, in particular sublimated. An essential aspect according to the invention includes in particular the focusing of the beam onto the adhesive layer itself, so that the substrates bounding the adhesive layer are as far as possible not heated by the beam or at least not directly. In the case of substrates with a correspondingly good thermal heat conductivity, such heating would lead to spreading of the heat over the entire substrates. The embodiment according to the invention is thus demarcated from the prior art, in particular by the focusing. In the prior art, such beams are focused predominantly via a substrate side, i.e. through the substrate, in particular the carrier substrate, onto the adhesive layer, as a result of which intense heating of the substrate occurs.

The adhesive strength may be different with respect to the product substrate and the carrier substrate, wherein the lower adhesive strength is usually decisive for the detaching force to be applied during the detachment. The decisive factor is also the location at which the greatest adhesive strength is present. According to an advantageous embodiment of the invention, therefore, provision is made such that the adhesive strength is greater at a peripheral edge region of the substrate stack than in the centre, particularly with regard to a smaller area. In the semiconductor industry, it is common practice to indicate the strength between two surfaces by the energy that is required to separate the two surfaces from one another. The energy is stated relative to a unit area and in J/m². This strength can subsequently also be understood to mean the adhesive strength of the adhesive with which it holds the surfaces of the two substrates together. According to the application according to the invention, the adhesive strength is in particular less than 2.5 J/m², preferably less than 2.0 J/m², still more preferably less than 1.5 J/m², most preferably less than 1.0 J/m², with utmost preference less than 0.1 J/m². In the case of a complete removal of the adhesive, the adhesive strength is reduced in particular to 0 J/m², since no further bonding agent is present between the two substrate surfaces. It is assumed here that the substrate surfaces are not jointed together on account of their adhesion. The above adhesive strength values for the edge region apply to a ZoneBond™ substrate stack.

According to a further, in particular independent, aspect of the invention, provision is made such that specifically selected layers of a multi-layer system between the two substrates are detached in a targeted manner, in particular by a beam directed at least predominantly, preferably exclusively, onto the selected layer. A substrate stack can be held together in particular by a multilayer system of a release layer and an adhesive layer. As a result of focusing the electromagnetic beam onto one of the two layers, a particularly efficient detachment of the two substrates from one another takes place.

In particular, the invention describes a method and a device for the debonding of two substrates, in particular two substrates which have been temporarily bonded together with the aid of the ZoneBOND® technology. The idea according to the invention preferably includes using optical elements, in particular a focusing unit, in order to direct, in particular concentrate, electromagnetic radiation, in particular a laser beam, more preferably a UV laser beam, onto the interface between the two substrates.

In a very particular embodiment according to the invention, the laser can be liquid-conducted. For this purpose, a liquid is conveyed onto the layer to be removed between the substrate stack and the laser is coupled into the liquid. The laser ensures a rapid and efficient detachment of the adhesive. The liquid can promote the detachment of the adhesive, but is also, in particular chiefly, responsible for the carrying away the detached adhesive. The pressure of the liquid amounts in particular to more than 1 bar, still more preferably more than 1.1 bar, most preferably more than 1.2 bar, with utmost preference more than 1.4 bar. The liquid is in particular:

Water, in particular distilled water

Solvent, in particular
PGMEA, mesitylene, isopropanol and/or limonin.

The liquid is preferably constituted such that it is at least partially, preferably predominantly, transparent for the used wavelength of the coupled-in light. Furthermore, the liquid beam is preferably guided in such a way that no bubble formation occurs, at which refraction unfavourable to the embodiment according to the invention could arise.

The embodiment according to the invention can be applied to systems in which different materials, in particular adhesives, in particular with different chemical and/or physical properties, can be applied upon one another or also beside one another.

In the first case, a layer system comprising a plurality of materials, in particular adhesives, is present. In special embodiments according to the invention, the adhesives can also be replaced by other materials which do not necessarily have adhesion properties, such as for example release materials.

In the second case, it is a system wherein a first adhesive is applied at the periphery, whilst a second material, in particular another adhesive, is present around the centre. Such an embodiment is disclosed in publication U.S. Pat. No. 7,910,454 B2. The application of a plurality of adhesives differing in their chemical and/or physical properties would also be conceivable, said adhesives being applied in the form of ever smaller rings on the carrier and/or the substrate. The centre is then filled by a last material, in particular adhesive.

Substrates in the sense according to the invention can in particular be semiconductor substrates. The product substrate preferably comprises functional components, in particular chips. The method according to the invention is suitable primarily for carrier substrates and/or product substrates, the material whereof is not transparent for electromagnetic radiation of a specific wavelength required for the detachment of the bonding layer.

The focusing takes place in particular with the aid of lenses. According to the invention, only the interface, in particular at least predominantly, preferably almost exclusively, the bonding layer present in the interface between the two substrates, in particular an adhesive, in particular a bonding adhesive, is influenced by the radiant power of the electromagnetic radiation. The adhesive strength is reduced, in particular locally, by the amount of radiation introduced into the bonding layer.

In a particularly preferred embodiment according to the invention, the electromagnetic radiation, in particular high-energy laser light, is brought as close as possible to the interface with the aid of a light guide. The light guide can comprise optics at its end facing towards the interface, said optics permitting additional focusing or manipulation of the electromagnetic radiation.

In other words, the essence of the invention comprises in particular the targeted direction, in particular focusing, of the electromagnetic radiation, in particular UV light, more preferably UF laser light, onto the outer regions of the bonding layer, in particular a temporary bonding adhesive. This preferably takes place without heating of the substrates by the electromagnetic radiation.

The use of solvent can preferably be completely dispensed with. Instead of a wet-chemical process, therefore, a dry-physical and/or dry-chemical process is preferably used.

The use of different electromagnetic sources for generating a beam for electromagnetic radiation is disclosed, said electromagnetic sources being able to be used for the detachment according to the invention:

microwave source,

infrared source,

source emitting visible light,

UV source

x-ray source

In particular, any source is conceivable that is suitable for bringing about the separation according to the invention of the carrier substrate, in particular by dissolution, most preferably by sublimation, of the bonding layer, from the product substrate by means of electromagnetic waves. The electromagnetic radiation of such a source can be incoherent or coherent. All sources which emit coherent electromagnetic radiation (lasers) are preferred. A microwave source that emits coherent microwave beams is referred to as a maser.

Coherence describes spatial and/or temporal coherence in the remainder of the patent specification.

An important physical parameter of the electromagnetic radiation used is the intensity. The intensity is stated in watts. The intensity of the electromagnetic radiation is in particularly greater than 0.1 watt, preferably greater than 1 watt, still more preferably greater than 100 watt, most preferably greater than 1000 watt, with utmost preference greater than 10 kilowatt.

According to a development of the invention, a pulse-mode operation of the source employed for the electromagnetic radiation is provided. As a result of a relatively high intensity and power density, heat transfer from the adhesive to the substrates can occur. In order to prevent such a heat transfer as far as possible, pulsed electromagnetic beams are preferably used. The pulse duration is in particular less than 10 seconds, preferably less than 1 second, still more preferably less than 1 microsecond, most preferably less than 1 nanosecond, with utmost preference less than 1 picosecond.

In a further embodiment according to the invention, the wavelengths used are selected depending on the given material used that is to be dissolved, in particular adhesive. The wavelengths are preferably selected such that the absorption capacity of the adhesive is at a maximum. Penetration of the electromagnetic radiation into great depths of the bonding layer, and an associated unnecessary and undesired heating of the substrates, is thus prevented. The wavelength is in particular selected such that, with a material/adhesive present, 95% of the radiant power is absorbed at less than 10 mm, preferably less than 5 mm, still more preferably less than 3 mm, most preferably less than 2 mm, with utmost preference less than 1 mm. The person skilled in the art calculates the corresponding wavelength-dependent absorption coefficient ε from the Lambert-Beer law

$$P ( d ) = {P}_{0} * e - ɛ d or$$

$$log \frac{P ( d )}{P o} = log 0 .05 = - ɛ d$$

### Optional Preparation of the Bonding Layer

The bonding layer can be prepared by additives in order to react particularly sensitively to certain kinds of electromagnetic radiation. In a particular embodiment according to the invention, the additives are not present in the bonding layer from the outset, but only added during and/or after its deposition on a substrate. In particular, the addition of such additives is limited to the outer edge of the bonding layer (peripheral edge region). The peripheral edge region is defined in particular as a circular ring with a width B. Width B is in particular equal to radius R of the substrate, B preferably being less than 95% of R, still more preferably less than 50% of R, still more preferably less than 10% of R, most preferably less than 1% R, with utmost preference less than 0.1% of R.

The mole fraction is used to establish the preferred quantity of additives. The mole fraction gives the ratio between the quantity of the additive (in mole) and the sum of the quantities of additive and other components of the bonding layer, in particular adhesive, (in mole). The mole fraction is thus dimensionless. If an adhesive is used without additives, the mole fraction for the additives is zero. If the molar ratio between adhesive and additive is 0.5, there is a molar mixing ratio of 1:1. The mole fraction of the additive is in particular less than 0.5, preferably less than 0.25, still more preferably less than 0.1, most preferably less than 0.01, with utmost preference less than 0.001. The smaller the mole fraction, the less additive is present in the adhesive and the less the additive influences the actual functional property of the adhesive. A smaller quantity of additive usually leads to a correspondingly low sensitivity to the electromagnetic radiation.

The additives are in particular:

Molecular compounds, in particular
Water

Polymers
Wavelength-sensitive polymers
Heat-sensitive polymers

Metals, in particular
Metallic particles, in particular
   nanoparticles, in particular of
      Cu, Ag, Au, Pt, Al, W, Co, Ni, Ta, Nb, Fe
      Alloys of Cu, Ag, Au, Pt, Al, W, Co, Ni, Ta, Nb, Fe
      Oxides

### Electromagnetic Radiation

The propagation direction of the electromagnetic radiation is denoted by the flight direction of the photons. For those sources whose electromagnetic beams are to be interpreted primarily in the sense of the Maxwell Theory, propagation direction should be understood to mean the direction of the Poynting vector. This applies especially to the microwaves mentioned below.

In a first embodiment according to the invention, a source is positioned such that a maximum of the radiation density of emitted electromagnetic radiation strikes the bonding layer. Here, the use of optical elements for focusing the electromagnetic radiation is in particular dispensed with. This embodiment according to the invention is especially preferred when the wavelength of the electromagnetic radiation used is greater than a thickness d of the bonding layer. The electromagnetic radiation used in this case lies in the region of larger wavelengths and thus smaller frequencies. The electromagnetic beams thus generated are preferably observed with the aid of the wave image and the Maxwell equations of electrodynamics. In a preferred embodiment according to the invention, microwaves are used. The microwaves are preferably generated by one of the following microwave tubes:

Velocity-modulated tubes, in particular
Cross-field tubes, in particular amplitron, magnetron or stabilotron or
Linear-beam tubes, in particular klystron.

The generated microwaves preferably strike the bonding layer with a divergence angle β of less than 10°, preferably less than 5°, still more preferably less than 1°, most preferably less than 0.1°

For the use of this embodiment according to the invention, the material of the bonding layer (with or without additive) is sensitive to irradiation with microwaves.

In a development of the invention, the material of the bonding layer, in particular the adhesive, comprises functional groups, which react to the microwave beams in such a way that breaking of polymer chains is brought about by the strong electromagnetic alternating load.

According to an alternative development, additives are added to the bonding layer, said additives reacting in a sensitive manner to the microwave radiation, in particular leading to intense heating. The additive is in particular water. The impacting microwave radiation primarily brings about a change in the oscillation state of the molecules or side chains, in particular functional units, of the adhesive or the additives. Accordingly, an independent aspect according to the invention includes increasing the temperature by capacitive heating.

In a further embodiment according to the invention, infrared light is used to act on the bonding layer in the edge zone. In particular, optical elements are used for focusing the electromagnetic radiation. Thickness d of the bonding layer is preferably set in a magnitude range of the wavelength of the infrared radiation. Far infrared light has a wavelength range from approx. 1000 μm to approx. 50 μm, middle infrared light lies in the wavelength range from approx. 50 μm to approx. 3 μm and near infrared light has correspondingly smaller wavelengths up to approx. 0.78 μm. Thickness d of the bonding layer is set in this case in particular between 1 μm and 30 μm, wherein the dimensions of any typography of a product wafer to be bonded, said typography to be embedded in the bonding layer, can be taken into account.

Through the selection of an infrared source, it is thus possible to select an infrared wavelength which can be focused by means of optical elements onto the material of the bonding layer, without the substrates being adversely affected. The optical elements are in particular convergent lenses.

A central idea in the use of infrared light comprises in particular the local heating of the bonding layer by the optical elements according to the invention and the infrared source, in particular without heating the substrates directly by the infrared radiation. The adhesive used should therefore preferably experience dissolution due to heat, become decomposed and at least change its adhesion properties (reduce adhesive strength).

In a further embodiment according to the invention, visible light is used to dissolve the temporary bond. The employed material of the bonding layer, with or without added additives, should react sensitively to the photons of the visible light. Visible light primarily influences the electrons in molecules, in particular those of the outer shells. The irradiation with light leads to electron transfer processes, which can transfer electrons from one molecular orbital into another molecular orbital. If the frequency, and therefore the energy, of the photons is great enough, the electron transfer processes can bring about changes in the bonding structure of the molecules, which change the adhesion properties of the material acted on or decompose or dissolve the latter or at least reduce the adhesive strength. These effects are used for the present embodiment. The region of UV radiation is preferably selected.

In a further, preferred embodiment according to the invention, use is made of UV light. The frequency and the energy of the UV light photons are in particular selected such that, according to the invention, they can bring about relevant changes in the bonding structure of molecules of the material of the bonding layer. In particular, as a result of the irradiation of the material with the UV light, there is a chemical change in the adhesive, in particular a destruction of (covalent) bonds or a polymerisation process, which changes the adhesive strength of the material in a relevant manner. Any other chemical and/or physical process that reduces the adhesive strength in a relevant manner and that thus permits the debonding process according to the invention would also be conceivable.

According to a further conceivable embodiment according to the invention, use is made of X-radiation to change the chemical and/or physical properties of the material of the bonding layer. Focusing of X-radiation, which is preferably carried out, is not possible using conventional refraction optics, since the refractive index for virtually all materials and such a high frequency lies close to 1.0 and a conventional material does not therefore permit refraction and also therefore does not permit focusing of the x-ray beams. Optical elements are however known that can focus x-ray beams by the physical effect of the total reflection. These optical elements comprise in particular a plurality of capillaries, which are embedded with certain curvature radii in a matrix. The curvature radius is selected in particular such that a penetrating x-ray beam is conducted at least predominantly, preferably exclusively, by total reflection along the capillaries.

A divergent x-ray beam can be focused in a point by the preferred arrangement of a plurality of capillaries. These optical elements are called capillary optics. The diameter of the focal point is in particular less than 5 mm, preferably less than 3 mm, still more preferably less than 1 mm, most preferably less than 0.1 mm, with utmost preference less than 0.01 mm.

In a development of the invention, one of the mentioned sources can be used in combination with a solution bath, so that the action on the bonding layer adhesive is on the one hand (fluid) chemical and on the other hand photophysical or photochemical. As a result of the twofold effect to the action thus generated, a particularly preferred detachment of the bonding layer can be brought about, in particular exclusively, from the edge region. The solution bath to be selected comprises at least one component in which the material of the bonding layer is dissolved, i.e. in this regard is selective, in particular in connection with the optical action.

### Optical Systems

A local action on the material of the bonding layer, related in particular to a partial region, preferably a peripheral edge region, is common to all the embodiments according to the invention.

In order to detach completely a radially symmetrical substrate bond of a substrate stack, a relative movement between the source or the beam and the substrate stack is advantageous according to an embodiment of the invention. The construction outlay and the costs for a multiplicity of optical systems can thus be reduced.

According to a first embodiment, the source is moved around the substrate stack in a closed path, in particular an orbit, while the latter is rotated in the opposite direction around its own axis. The normal of the orbit of the source and the rotation axis of the substrate stack are parallel to one another, so that the beam can act on the bonding layer during the movement.

In a second embodiment, only the source is moved around the substrate stack in a closed path, in particular an orbit, while said substrate stack is at rest. A second motor for moving the substrate stack can thus be dispensed with.

In a third, in particular preferred embodiment, the source is at rest, while the substrate stack is rotated around a symmetrical axis. The substrate stack is in particular fixed on a substrate sample holder, which is mounted rotatably. The substrate stack is preferably mounted in such a way that the distance between the focus of the electromagnetic radiation and the outer edge of the bonding layer remains constant up to a predetermined tolerance during the rotation of the sample holder. The tolerance is in particular less than 5 mm, preferably less than 3 mm, still more preferably less than 2 mm, most preferably less than 1 mm, with utmost preference less than 0.5 mm.

The frequency of the movement, in particular rotation, of the source and/or of the substrate stack is stated in rounds/revolutions per minute (rpm). The frequency is in particular less than 5000 rpm, preferably less than 2500 rpm, still more preferably less than 1000 rpm, most preferably less than 100 rpm, with utmost preference less than 10 rpm.

The optical systems have in particular the task of focusing or concentrating the emitted electromagnetic radiation on a limited portion of the adhesive. The electromagnetic radiation preferably does not strike the substrates or only does so to a small extent, in particular not directly or only to a small extent directly.

In a particular extension of the embodiments according to the invention, the source is designed such that the focal point can be or is readjusted, in particular automatically, with the advancing detachment process. Optimum tracking of the focal point in the bonding layer still to be detached is thus brought about. An optimum dissolution rate is at all times guaranteed as a result of the tracking of the focal point. The tracking of the focal point takes place in particular by the translational and/or rotational movement of the source and/or by adaptation of the optical elements, in particular by using adaptive optics, which can continuously change the focal length. The tracking of the focal point takes place manually, more preferably automatically, in particular by suitable software and/or hardware and/or firmware.

A ratio between the amount of radiation absorbed by the bonding layer and the amount of radiation absorbed by the substrates is in particular greater than 0.5, preferably greater than 0.8, still more preferably greater than 0.9, most preferably greater than 0.95, with utmost preference greater than 0.99.

The optical systems can comprise all optical elements that can influence the electromagnetic radiation of the source in the inventive manner. These include, in particular, the following optical elements, individually or in combination:
Lenses, in particular concave lenses and/or convex lenses and/or convex-concave lenses and/or Fresnel lenses and/or aspherical lenses and/or
Collimators
Diaphragms
Mirrors, in particular hot or cold mirrors, preferably parabolic mirrors and/or elliptical mirrors and/or planar mirrors and/or
Diffraction elements, in particular diffraction grating and/or
Polarisers, in particular polarisers for generating linearly polarised light and/or polarisers for generating elliptically polarised light.

Each of the optical elements and/or the entire optical system can be mounted on a table, which has a plurality of degrees of freedom, in order to steer or adjust the focal point onto the bonding layer, in particular the peripheral edge region.

The table preferably has a translation unit with three degrees of freedom for the translation and a rotation unit with three degrees of freedom for the rotation. The travel path of the translation unit is in particular greater than 1 μm, preferably greater than 1 mm, still more preferably greater than 10 mm, most preferably greater than 100 mm. The accuracy of the translation unit is in particular better than 1000 μm, preferably better than 100 μm, still more preferably better than 10 μm, most preferably better than 1 μm. The rotation range of the rotation unit is in particular greater than 0.1°, preferably greater than 10, still more preferably greater than 10°, most preferably greater than 100°. The accuracy of the rotation unit is in particular better than 5°, preferably better than 1°, still more preferably better than 0.1°, most preferably better than 0.01°.

### Detectors

In a development of the invention, a detector is provided for measuring a physical and/or chemical signal at at least one point of the impacting or action of the electromagnetic radiation on the bonding layer, preferably as a unit connected to the source and/or optics. By measuring and evaluating the signal, it is possible to estimate the extent to which the inventive detachment process of the material of the bonding layer has advanced in the peripheral edge region. The detachment process can thus be controlled much more efficiently.

A locally limited measurement of the material properties of the bonding layer is enabled by a reduction of the debonding process to the peripheral edge region and/or the use of a locally limited action on the bonding layer. The following types of detector can in particular come into consideration individually or in combination:

Physical detectors, in particular
Optical (spectroscopic) detectors, preferably UV-VIS spectrometers and/or Raman spectrometers and/or infrared spectrometers and/or
Optical (visual) detectors, in particular microscopes and/or discharge detectors and/or fluorescence detectors and/or phosphorescence detectors and/or
Mechanical detectors, in particular force detectors and/or resonant frequency/oscillation detectors and/or ultrasound detectors and/or

Chemical detectors, in particular gas detectors.

The irradiation time of the bonding layer for the complete debonding of the substrate stack is in particular less than 30 minutes, preferably less than 15 minutes, still more preferably less than 1 minute, most preferably less than 30 seconds, with utmost preference less than 5 seconds.

### Sample Holder

The substrate stack is fixed in particular on a sample holder. The Sample holder can be a sample holder with electrostatic, magnetic, adhesive, vacuum-controlled or mechanical fixing.

In a first embodiment according to the invention, the sample holder preferably has a base surface, in particular a fixing surface, which is larger than the area of the substrate stack to be fixed.

In particular, the diameter of the sample holder is selected greater than or equal to the diameter of the substrate stack to be fixed. The diameter of the sample holder is in particular the same size, preferably 1.2 times larger, still more preferably 1.3 times larger, most preferably 1.4 times larger than the diameter of the substrate stack to be fixed.

If the optical elements for fixing the electromagnetic beams are located at the same height as the bonding layer, the sample holder is preferably set back in order to enable the positioning of the optical elements. According to an advantageous embodiment, the sample holder thus has a base surface, in particular a fixing surface, which is smaller than the area of the substrate stack to be fixed. In particular, the diameter of the sample holder is selected larger or smaller than the diameter of the substrate stack to be fixed. The diameter of the sample holder is in particular the same size, preferably less than 0.9 times, still more preferably less than 0.6 times, most preferably less than 0.5 times the diameter of the substrate stack to be fixed.

In a further conceivable embodiment, the substrate stack is fixed on a tape, which is stretched on a frame. The in particular back-thinned or otherwise processed product substrate is fixed on the tape with its external surface, whilst the internal surface is fixed with the adhesive to the carrier substrate.

In a very particular embodiment according to the invention, the surface of the external carrier substrate can be fixed on a sample holder, while the frame is fixed by mechanical separating means and is raised during the process according to the invention. As a result of the raising of the frame, the tape is stretched and thus supports the debonding process in the periphery. Due to the arising wedge, the electromagnetic radiation of the embodiment according to the invention correspondingly receives more space to penetrate into the depth of the interface.

### Process

According to a first embodiment of the process according to the invention, the action on the bonding layer takes place by means of a device, wherein at least one focal plane F of the beam with electromagnetic radiation and an adhesive layer plane K are in parallel with one another, in particular congruent or aligned.

In a first process step, the positioning of the substrate stack on the sample holder takes place. The positioning of the substrate stack preferably takes place in such a way that the bonding layer is arranged at least in the proximity of the optical axis and/or focal plane F of the electromagnetic radiation. The substrate stack is adjusted in particular by a z-translation unit in the height (z-direction), until adhesive layer plane K of the bonding layer to be detached correlates with focal plane F. Adhesive layer plane K is understood to mean a plane parallel to the bonding layer and centred with respect to a thickness d of the bonding layer. The distance between adhesive layer plane K and focal plane F in the z-direction is in particular less than 5 mm, preferably less than 1 mm, still more preferably less than 0.1 mm, most preferably less than 0.01 mm.

In a second process step, a fine adjustment of the optical elements takes place for adjusting the electromagnetic radiation relative to thickness d. As a result of the fine adjustment, the distance between adhesive layer plane K and focal plane F can be further reduced. In particular, the distance after the fine adjustment is less than 5 mm, preferably less than 0.1 mm, still more preferably less than 0.01 mm, most preferably less than 0.001 mm. If a correct adjustment of the two planes with respect to one another has already taken place by the first process step according to the invention, this second process step according to the invention can accordingly be dispensed with. Corresponding distance measuring means are assumed to be known and are optionally disclosed as an advantageous embodiment of the invention.

In a third process step, an adjustment of the focus in the bond interface (bonding layer) takes place. The focus is adjusted onto a focal point inside or at the edge of the bonding layer. The focus is preferably slightly inside the bonding layer. The distance of the focal point from the peripheral edge of the bonding layer lies in particular in the range between 0 mm and 5 mm, preferably between 0 mm and 4 mm, still more preferably between 0 mm and 3 mm, most preferably between 0 mm and 2 mm, with utmost preference between 0 mm and 1 mm.

The first three process steps according to the invention should in the optimum case be carried out only once in order to establish the correct position in the sample holder, the optical elements and therefore the focal plane or the focus. In a preferred embodiment, after the one-off adjustment, a plurality of substrate stacks with identical dimensions can be placed at the same position on the sample holder and be acted upon with the electromagnetic radiation without a renewed adjustment. In particular, focal plane F should be congruent with adhesive layer plane K and the focus should always have the same distance from the peripheral side edge.

According to the invention, a recalibration is mainly required when one of the geometrical parameters of the substrates and/or the thickness of the bonding layer changes. If desired, a calibration can however also be carried out with each new substrate stack. Several reference values are preferably established and checked and a new adjustment is carried out only in the case of a divergence being established. The process sequence is thus speeded up.

In a fourth process step according to the invention, the source of the electromagnetic radiation is switched on, inasmuch as this has not already happened in the calibration process. The intensity is increased to the value specified/required for the material of the bonding layer and is limited/concentrated as far as possible on the bonding layer by means of optical elements.

If the electromagnetic radiation permits the use of suitable lenses, focusing on the electromagnetic radiation on the bonding layer takes place. Alternatively or in addition, diaphragms are used in order to minimise the influencing of the substrates by the electromagnetic beams.

In a fifth process step, the rotation of the substrate stack and/or the source takes place, so that the electromagnetic radiation, directed or concentrated in particular onto a point, acts on the peripheral edge region of the bonding layer around the whole periphery. By means of this process step, at least the peripheral region is weakened, in such a way that the actual debonding process can be carried out in a further, in particular last, process step according to the invention.

An influencing depth or penetration depth of the electromagnetic radiation in the material of the bonding layer is in particularly greater than 100 μm, preferably greater than 1 mm, still more preferably greater than 5 mm, most preferably greater than 10 mm. The influencing depth is understood to mean the depth within which inventive weakening, in particular complete dissolution, preferably sublimation, of the adhesive takes place. Adhesive lying behind the influencing depth is therefore not affected, i.e. dissolved, by the embodiment according to the invention. In particular, a further aspect according to the invention arises from this, since a reflection of the electromagnetic radiation at the substrate surfaces facing the adhesive is for the most part, preferably completely, prevented by the avoidance of an excessively great penetration depth.

While a weakening of the adhesive strength is carried out in the peripheral edge region, forces, in particular at least a normal force, can be applied to the substrates, especially at their peripheral regions, in order to bring about or assist a separation of the substrates. Furthermore, a rejoining of the substrates, in particular by a renewed bonding, is prevented by the forces and the associated distancing of the substrates from one another. The applied forces can be point-like and/or linear and/or two-dimensionally extending forces. In the case of a point-like force, the force is in particular greater than 0.001 N, preferably greater than 0.1 N, still more preferably greater than 10 N, most preferably greater than 150 N. In the case of linear and/or two-dimensionally extending forces, the corresponding pressures can be ascertained by division of the aforementioned forces by the line length or the size of the area.

In a sixth process step, the detachment (debonding) of at least one of the two substrates from the substrate stack takes place by the removal of one or both substrates from one another. The removal takes place in particular by the application of a tensile and/or a shearing force. In particular, the removal takes place by traction, shearing or bending.

In particular embodiments, the separation of the two substrates can take place independently after the action taking place according to the invention, in particular solely by the effect of gravitation. In particular, the substrate stack can be fixed on its substrate opposite to the gravitation direction, while the process according to the invention weakens the peripheral region of the bonding layer. This embodiment according to the invention particularly preferably takes place in a solvent bath, so that the peripheral region is acted upon not only by the electromagnetic radiation, but also by the chemical. Another plant for debonding is described for example in patent specification WO2012/139627A1. A clamping ring around the entire periphery is used therein to subject the carrier substrate to bending in order to detach the same from a product substrate. The embodiment according to the invention could assist the debonding process by an advance weakening of the peripheral region.

In an alternative, second process according to the invention, the action on the bonding layer takes place by means of a device, wherein adhesive layer plane K has an angle of inclination relative to the focal plane. The angle of inclination is greater than 00, in particular greater than 25°, more preferably greater than 50°, most preferably greater than 75°, with utmost preference 90°. In particular, the action on the peripheral edge region of the bonding layer thus takes place by means of at least one of the substrates.

The described features apply analogously to the device according to the invention and the method according to the invention as well as the use according to the invention.

Further advantages, features and details of the invention emerge from the description of preferred examples of the embodiment and with the aid of the drawings.

### BRIEF DESCRIPTION OF THE DRAWINGS

FIG. 1 shows a diagrammatic cross-sectional view, not true to scale, of a wafer stack bonded over the entire area,

FIG. 2 shows a diagrammatic cross-sectional view, not true to scale, of a wafer stack bonded predominantly in a peripheral edge region (ZoneBOND®),

FIG. 3a shows a diagrammatic cross-sectional view, not true to scale, of a first embodiment of the invention,

FIG. 3b shows a diagrammatic view, not true to scale, of the first embodiment according to FIG. 3a,

FIG. 4a shows a diagrammatic cross-sectional view, not true to scale, of a second embodiment of the invention,

FIG. 4b shows a diagrammatic view, not true to scale, of the second embodiment of the invention according to FIG. 4a,

FIG. 5a shows a diagrammatic cross-sectional view, not true to scale, of a third embodiment of the invention,

FIG. 5b shows a diagrammatic cross-sectional view, not true to scale, of the third embodiment of the invention according to FIG. 5a and

FIG. 6 shows a diagrammatic side view, not true to scale, of an optimised detachment process.

Identical components or components with the same function are denoted by the same reference numbers in the figures.

### DETAILED DESCRIPTION OF THE INVENTION

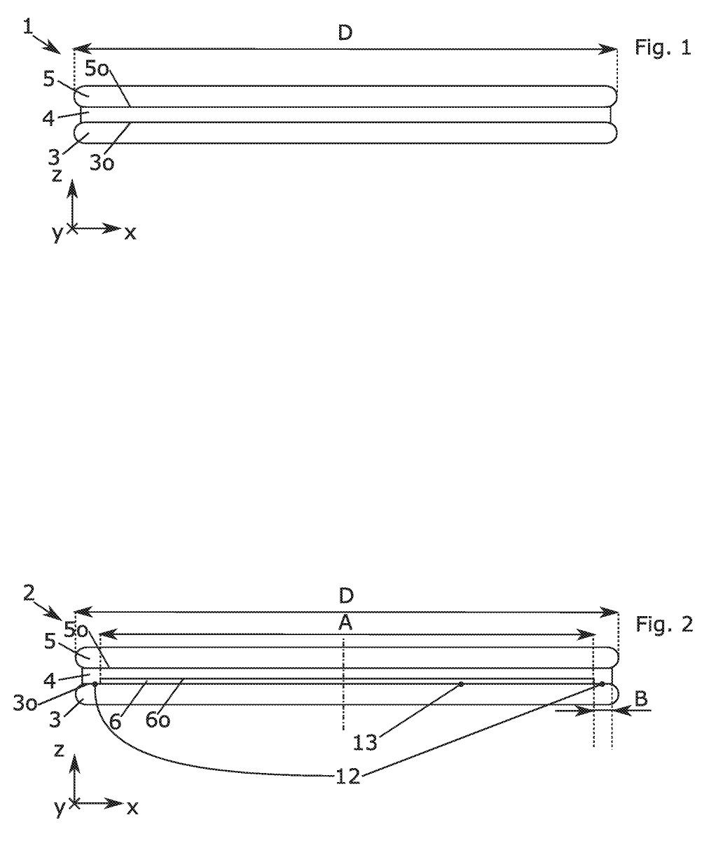

FIG. 1 shows a substrate stack constituted as a wafer stack 1 bonded over the entire area, comprising a carrier substrate 3, a bonding layer 4 constituted as an adhesive layer and a product substrate 5. The two substrates 3, 5 have an identical diameter D in the example of the embodiment shown. Substrate surfaces 3o, 50o of carrier substrate 3 and product substrate 5 are covered by bonding layer 4 at least predominantly, preferably over the entire area, on parallel faces lying opposite one another.

FIG. 2 shows a substrate stack constituted as a ZoneBOND®-bonded wafer stack 2, comprising carrier substrate 3 prepared with a low-adhesion (or non-adhesive) layer 6, product substrate 5 and bonding layer 4.

Low-adhesion layer 6 has been applied centrally on carrier substrate 3 inside central circular area 13 with a diameter A less than diameter D. A peripheral edge region 12 thus formed is in particular a circular ring with a, in particular circumferentially constant, width B (in particular minus a radius of curvature at the transition to the lateral periphery of substrates 3, 5).

Bonding layer 4 adheres predominantly to carrier substrate surface 3o along edge region B. An adhesive strength in peripheral edge region 12 is disproportionately great in relation to the adhesive strength in the region of central circular area 13, where the adhesive strength is reduced at least with respect to carrier substrate 3, in particular virtually to zero. According to the application according to the invention, the adhesive strength in peripheral edge region 12 is greater than 0.1 J/m², preferably greater than 0.5 J/m², still more preferably greater than 1.0 J/m², most preferably greater than 1.5 J/m², with utmost preference greater than 2.0 J/m². According to the application according to the invention, the adhesive strength in the region of central circular area 13 is less than 1.0 J/m², preferably less than 0.75 J/m², still more preferably less than 0.5 J/m², most preferably less than 0.25 J/m², with utmost preference less than 0.01 J/m².

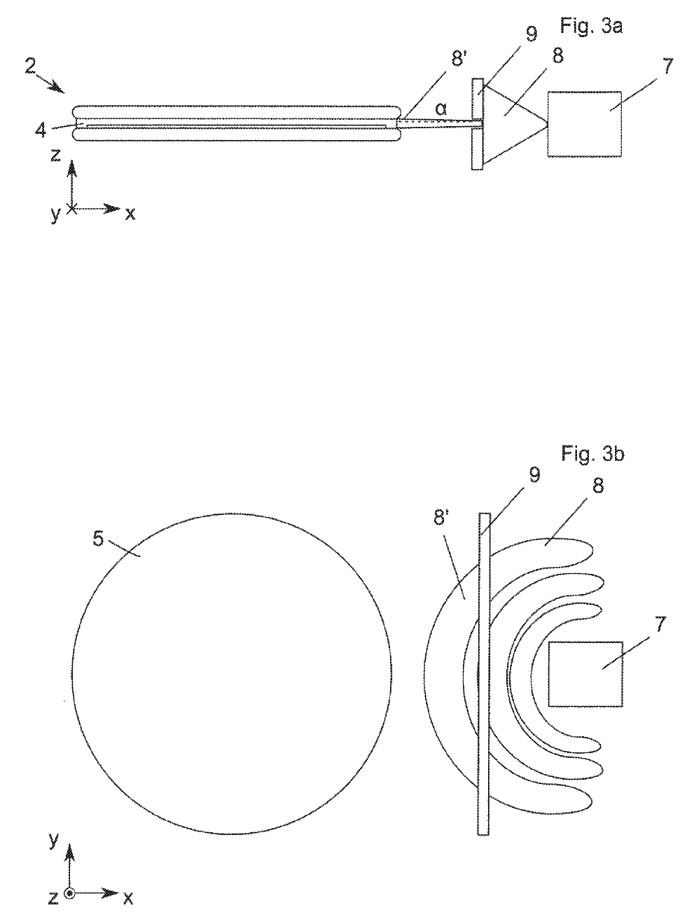

FIG. 3a shows a source 7 emitting long-wave electromagnetic beams, in particular a microwave source. Microwave source 7 emits a beam 8 directed onto the substrate stack. Beam 8 is preferably constituted by an electromagnetic field in the sense of the Maxwell equations of electrodynamics, in particular not as a quantized photon multiple-particle system. Beam 8 is concentrated at least predominantly on bonding layer 4, preferably by means of an optical element 9, in particular a diaphragm and/or a collimator.

After passage of beam 8 through optical element 9, the latter is changed, in particular reduced, concentrated or focused, to form a beam 8′. There thus leaves optical element 9 a beam 8′ with a non-vanishing divergence, described by divergence angle α, wherein beam 8′ is directed and changed in such a way that it almost exclusively directly strikes an end face of peripheral edge region 12 of bonding layer 4.

FIG. 3b represents diagrammatically from above the electrical field of the microwave radiation of beam 8, 8′. In the embodiment represented, optical element 9 confines beam 8 exclusively along the z-direction, so that the microwave beams inside the x-y plane (orthogonal to be z-direction) can freely extend at least in the direction of the substrate stack. The same applies to optical element 9 preferably around the slit diaphragm. The use of other optical elements that confine or focus microwave radiation 8 in a point-like manner would also be conceivable. However, since the microwave radiation is a long-wave electromagnetic radiation and any focusing by corresponding optical elements is always bound up with errors, in particular due to spherical or chromatic aberration, masking-out of the microwave radiation is regarded as a preferred solution for the confinement to bonding layer 4.

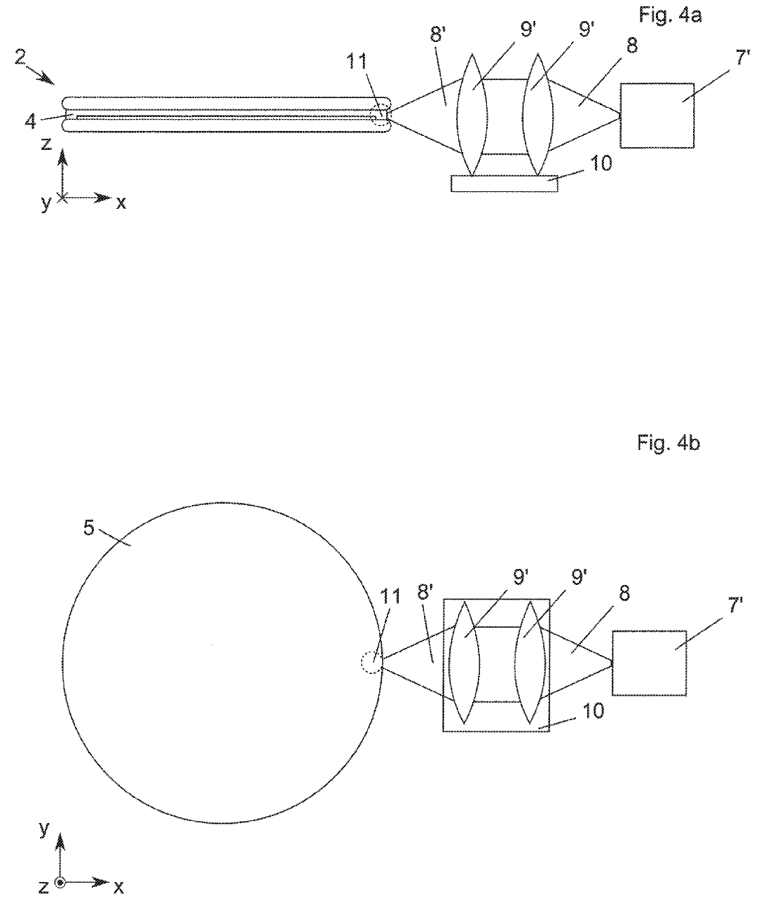

FIG. 4a shows a source 7′, in particular an infrared. VIS or UV source, which can generate an electromagnetic (photon) beam 8. The latter is directed and concentrated or focused as beam 8′ on a focal region 11 arranged inside bonding layer 4 by means of optical elements 9′, in particular lenses. Focal region 11 is preferably arranged in peripheral edge region 12.

Beam 8′ preferably does not strike carrier substrate 3 and/or product substrate 5. In contrast with the first embodiment according to the invention, the electromagnetic beams of source 7′ can be focused with optical elements 9′ into an extremely small focal region 11.

For the optimum positioning of optical elements 9′, the latter are preferably arranged on a table 10 in order to duly steer and optimise the optical path of the electromagnetic beams. Each optical element 9′ can be mounted on its own table or preferably all optical elements 9′ are mounted on the (single) table 10.

Source 7′ preferably emits a beam 8 constituted as a laser beam, in particular a UV laser beam. Lasers deliver highly collimated, very brilliant, coherent, monochromatic photon beams.

FIG. 4b shows that, by a combination of optical elements 9′ and a corresponding source 7′, focusing in both dimensions (y- and z-direction) is possible.

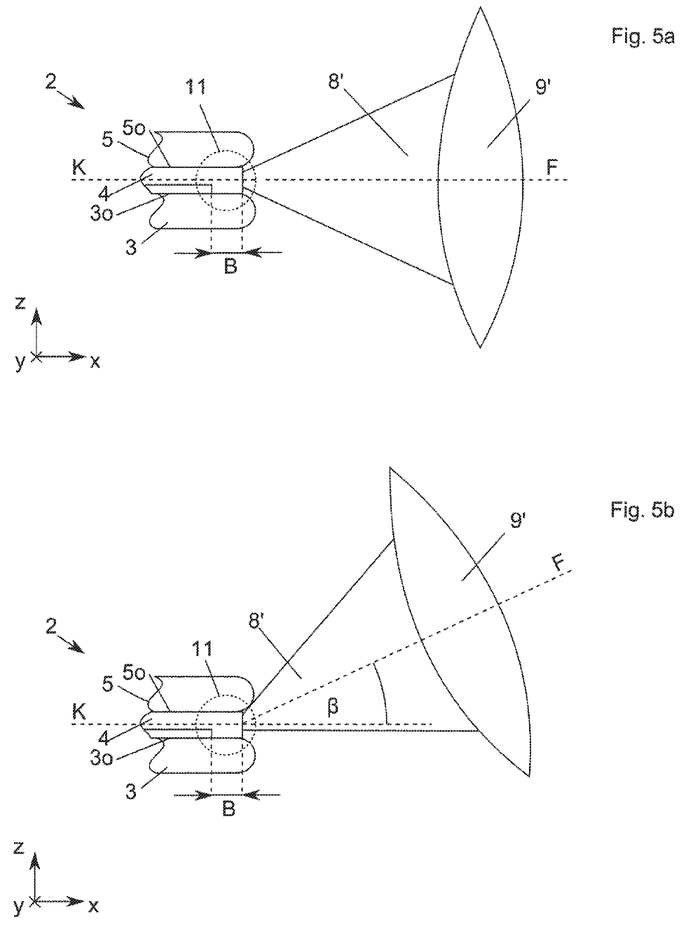

FIG. 5a shows optical element 9′ with a focal plane F, which is orientated parallel, in particular congruent, with respect to an adhesive layer plane K. Accordingly, angle β between focal plane F and adhesive layer plane K is zero.

FIG. 5b shows an embodiment, wherein optical element 9′ with a focal plane F is inclined by an angle of inclination β relative to adhesive layer plane K. Angle of inclination β is preferably adjustable.

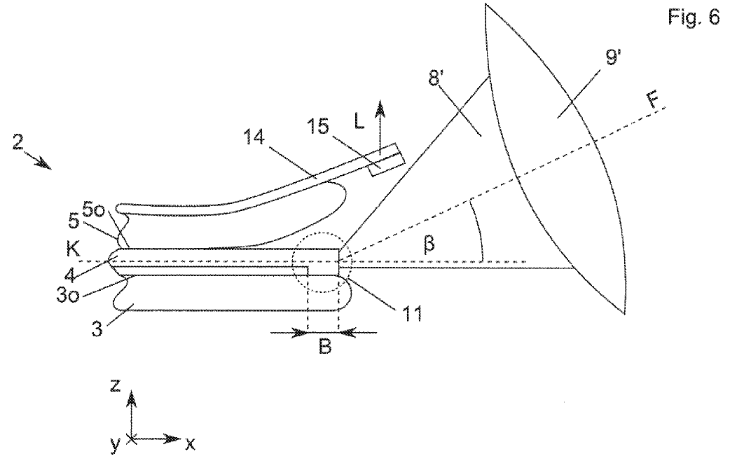

FIG. 6 shows an embodiment, wherein product substrate 5 has been fixed on a tape 14. Tape 14 is stretched over a frame 15.

By applying a force L on frame 15, raising of product substrate 5 in the peripheral region takes place and thus makes it for easier for the electromagnetic beams focused by optical elements 9′ to gain access to adhesive 4. Force L can be applied at any angle. The angle between the force direction of force L and the normal onto the carrier substrate is in particular less than 45°, preferably less than 35°, still more preferably less than 25°, most preferably less than 15°, with utmost preference 0°. Force L is less than 10 N, preferably less of the 5 N, most preferably less than 1 N, with utmost preference less than 0.5 N.

### REFERENCE LIST

1 SlideOff substrate stack
2 ZoneBOND® substrate stack
3 Carrier substrate
3o Carrier substrate surface
4 Adhesive
5 Product substrate
5o Product substrate surface
6 low-adhesion layer
7, 7′ source
8, 8′ beam
9, 9′ optical element
10 table
11 focal region
12 peripheral edge region
13 central area
14 tape
15 frame
α divergence angle
β angle of inclination
D diameter
A diameter
B edge zone width
K bonding layer plane
F focal plane
d thickness of bonding layer
L force

1-9. (canceled)

10. A method for detaching a carrier substrate from a substrate stack that is comprised of the carrier substrate, a product substrate, and a bonding layer that bonds the carrier substrate and the product substrate, wherein the bonding layer has an adhesive strength for bonding the carrier substrate and the product substrate, said method comprising:
directing a beam of electromagnetic radiation on the bonding layer to at least partially reduce said adhesive strength, wherein the electromagnetic radiation is a laser beam that is focused directly onto the bonding layer.

11. The method according to claim 10, wherein less than 50% of an amount of the electromagnetic radiation of the beam is absorbed by the carrier substrate and/or the product substrate.

12. The method according to claim 10, wherein the bonding layer comprises a material that is softened by the electromagnetic radiation.

13. The method according to claim 12, wherein the material of the bonding layer is selected from one of the following:
silicones, and/or
plastics.

14. The method according to claim 13, wherein the plastics are thermoplastics, and/or thermosetting plastics, and/or elastomers.

15. The method according to claim 13, wherein the material of the bonding layer is mixed with at least one additive.

16. The method according to claim 10, wherein the adhesive strength of the bonding layer is constituted so as to act at least predominantly in a peripheral edge region of the substrate stack.

17. The method according to claim 10, wherein the method includes directing the beam by means of optical elements onto the bonding layer, wherein the optical elements are arranged between a source of the beam and of the bonding layer.

18. The method according to claim 10, wherein the method includes orienting the beam towards the bonding layer such that an angle of inclination β between a radiation axis of the beam and an adhesive layer plane K of the bonding layer is less than 45°.

19. The method according to claim 10, wherein the method further comprises focusing and/or concentrating the directed beam.

20. The method according to claim 19, wherein the directed beam is focused and/or concentrated by at least one optical element.

21. The method according to claim 10, wherein the method further comprises directing the beam on a peripheral edge region of the substrate stack by a relative movement between the substrate stack and the beam or a source generating the beam.

22. The method according to claim 21, wherein the relative movement is a rotation.

23. A device for detaching a carrier substrate from a substrate stack, which is formed by the carrier substrate, a product substrate, and a bonding layer that bonds the carrier substrate and the product substrate, wherein the bonding layer has an adhesive strength for bonding the carrier substrate and the product substrate, the device comprising:
a source for emitting a beam of electromagnetic radiation, the beam of electromagnetic radiation being a laser beam, wherein the adhesive strength is at least partially reduced by directing the laser beam on the bonding layer; and
a focusing device for focusing the laser beam directly on the bonding layer.
